(19) United States
(12) Patent Application Publication
(10) Pub. No.: US 2025/0349525 A1
(43) Pub. Date: Nov. 13, 2025

(54) RECIRCULATION CONTROL FOR A PLASMA PROCESS USING A BYPRODUCT CONCENTRATION

(71) Applicant: APPLIED MATERIALS, INC., Santa Clara, CA (US)

(72) Inventors: Neela Ayalasomayajula, Karnataka (IN); Nasreen Chopra, Portola Valley, CA (US); Naga Ravikumar Varma Nadimpalli, Karnatake (IN); Vijay Sharma, Rajasthan (IN); Vijay Tripathi, Pradesch (IN); Gopi Chandran, Maharashtra (IN)

(21) Appl. No.: 19/196,919

(22) Filed: May 2, 2025

(30) Foreign Application Priority Data
May 9, 2024 (IN) 202441036757

(51) Int. Cl. H01J 37/32

(52) U.S. Cl. CPC H01J 37/32844; H01J 37/32357; H01J 37/3244; H01J 37/32981; H01J 2237/327

(57) ABSTRACT

A system includes a remote plasma source, a process chamber, an exhaust line connected to the process chamber, a recirculation line connected to the process chamber, and a sensor to measure a concentration of a byproduct, such as silicon tetrafluoride, in an exhaust of the processing chamber. The system also includes a controller to release the exhaust of the processing chamber through the exhaust line or the recirculation line based on the measured concentration of the byproduct in exhaust of the process chamber.

### CROSS REFERENCE TO RELATED APPLICATION(S)

The present application claims priority to Indian (IN) Provisional Patent Application No. 202441036757 filed on May 9, 2024. The entire contents of which is incorporated in its entirety.

### TECHNICAL FIELD

The present application relates to recirculation of exhaust of a process chamber during plasma processing. In particular, the present application relates to measurement of a byproduct (e.g., a fluorine-containing byproduct), such as silicon fluoride (e.g., silicon tetrafluoride), of a process (e.g., of a cleaning process) in a gas flow, and recirculation of exhaust to a process chamber based on a measured concentration of the byproduct.

### BACKGROUND

Many processes, such as processes for forming semiconductors, photovoltaics, displays, etc., use one or more gases to deposit layers, etch layers, clean substrates, and so on. For some processes a plasma is formed and used during deposition, etching, cleaning, etc. The gases used to generate radicals for these processes (e.g. NF₃, F₂, etc.) pose potential environmental hazard and can result in excessive wear of processing equipment. Currently, by-product gases of these processes are abated and wasted, resulting in high abatement costs and energy.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system includes a remote plasma source. The system further includes a process chamber. The system also includes an exhaust line connected to the process chamber and a recirculation line connected to the process chamber. The system also includes a sensor in at least one of the process chamber or the exhaust line, wherein the sensor may be configured to measure a concentration of a byproduct of a process in an exhaust of the process chamber. The system further includes a controller to release an exhaust of the process chamber through the exhaust line or the recirculation line based on the measured concentration of the byproduct in the exhaust of the process chamber.

In one aspect of the disclosure, a method for performing a plasma-based process in a process chamber includes generating a plasma using a remote plasma source. The plasma further includes fluorine radicals, where the fluorine radicals react with a silicon-containing film on one or more components of a process chamber to form a byproduct. The method further includes monitoring a concentration of the byproduct in an exhaust of the process chamber using a sensor. The method also includes releasing the exhaust through an exhaust line connected to the process chamber or a recirculation line connected to the process chamber based at least on the measured concentration of SiF₄ in the process chamber.

### BRIEF DESCRIPTION OF THE DRAWINGS

The present disclosure is illustrated by way of example, and not by way of limitation in the figures of the accompanying drawings.

FIG. 1 is a sectional side view of a substrate processing system including a sensor, according to some embodiments.

FIG. 2 is a graph illustrating the relationship between silicon tetrafluoride and fluorine radicals.

FIG. 3 is flow chart of one embodiment of a method for detecting and maintaining fluorine radical concentration via a plasma source.

FIG. 4 is a flow chart of one embodiment of a method for recycling processing gases to the processing chamber.

FIG. 5 is a block diagram illustrating a computer system, according to certain embodiments.

### DETAILED DESCRIPTION

An improved approach to plasma processes such as plasma-based cleaning processes and plasma-based deposition processes is described in embodiments herein. It should be understood that the process described herein can be applicable for any byproduct (e.g., such as any fluorine-containing byproduct) of a process (e.g., of a cleaning process) in an exhaust gas of a process chamber. For simplicity of explanation of the present disclosure, the byproduct will be described as silicon fluoride, or silicon tetrafluoride, which is a fluorine-containing byproduct of a reaction of fluorine with a silicon-containing film on an interior surface of a process chamber that may be formed during processes such as deposition processes, etch processes, and so on. However, it should be understood that the plasma-based cleaning processes discussed herein can also be performed based on measurement of other byproducts, such as other fluorine-containing byproducts. The specific species of byproduct would depend, for example, on the composition of a film to be removed from a chamber interior during cleaning and on a gas (e.g., a plasma) used for the cleaning, and on a reaction of the cleaning gases with such a film. In some embodiments, in which a cleaning gas other than fluorine is used, the byproduct may not be a fluorine-containing byproduct, but may instead be some other byproduct.

In embodiments, a concentration of silicon tetrafluoride (SiF₄) in an exhaust of a process chamber is measured during a plasma process, and a controller causes the exhaust to be exhausted to abatement or recirculated to a remote plasma source that generates plasma for the plasma process based on the measured concentration of SiF₄. In some embodiments, the sensor used to measure the silicon fluoride concentration may be a nondispersive infrared sensor. In some embodiments, the primary cleaning gas in process chamber cleaning is nitrogen trifluoride, NF₃, which produces fluorine radicals in a process chamber. During the cleaning process, several byproducts, including silicon tetrafluoride, are produced. In typical cleaning processes, the exhaust of the process chamber is sent to exhaust in abatement. However, the exhaust of the process chamber often includes unused fluorine (e.g., unreacted fluorine radicals, F₂, etc.). By sending the exhaust of the process chamber to abatement, such unused fluorine is wasted. Accordingly, in embodiments the exhaust of the process chamber is recycled or recirculated to increase utilization of the F₂ and to reduce the overall amount of NF₃ used for the plasma process, and therefore reduce cost of the plasma process and reduce carbon emissions of the plasma process.

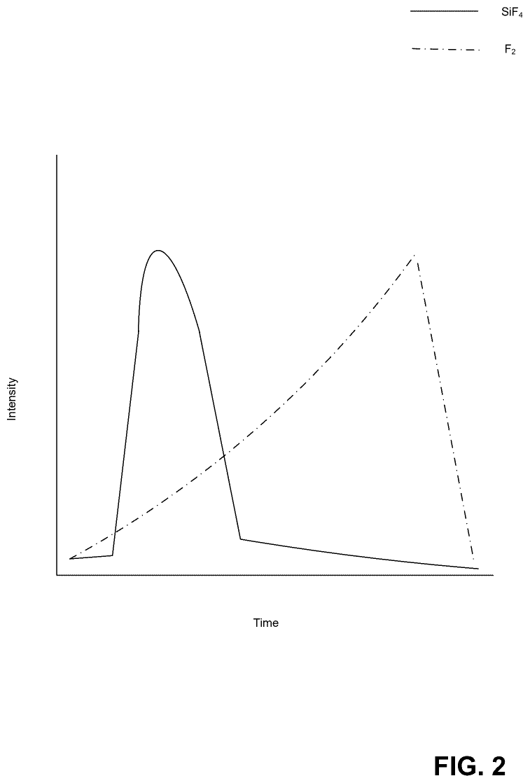

A byproduct, such as silicon tetrafluoride, may be an indicator of whether a clean process is completed or close to completed, or whether there is still additional silicon-containing film in a process chamber to be removed. As the byproduct or SiF₄ concentration decreases in the exhaust of the process chamber, this indicates that the amount of contamination in the process chamber is reduced. In some embodiments, while the concentration of the byproducts decreases over time, the concentration of fluorine radicals, such as F₂, increases. For example, if the byproduct is a silicon fluoride, then it was found that there is less silicon-containing film or contamination for the F₂ to react with in the process chamber. This relationship can be seen in FIG. 2. Thus, the present inventors have found that by monitoring and measuring the concentration of a byproduct, such as SiF₄, then they can control the recirculation of F₂ and other fluorine radicals to the remote plasma source to improve an efficiency of gas utilization for a plasma-based cleaning process. Additionally, recirculation of F₂ and/or NF₃ reduces emissions from the described processes. In embodiments, a combination of monitoring byproducts (such as SiF₄), recirculation of process gases such as Fluorine (F₂) and/or Argon to a plasma source for reuse, and filtering particles from an exhaust from a process chamber and/or of F₂ in exhaust recirculated back to a plasma source minimize an amount of time that process chamber cleaning is performed while minimizing amount of process gases (e.g., NF₃) used for the process chamber cleaning process.

Embodiments of the present disclosure relate to a manufacturing system that filters process chamber exhaust and recycles gases that can be used to generate additional radicals for manufacturing processes. Conventional plasma systems do not recirculate used gases or recycle used gases for generation of additional plasma and/or additional radicals. Rather, conventional plasma systems send used gases to abatement. In embodiments described herein, a system recirculates at least some process gases back to a plasma source (e.g., to a remote plasma source) to reuse those gases. Such reuse of gases, such as F₂ and/or Argon reduces gas waste (e.g., of fluorine gas).

In some embodiments, a system includes a remote plasma source before the process chamber. The remote plasma source generates the plasma for the process chamber, where the radicals in the plasma can be extracted to be used in the process chamber. The system also includes an outlet gas line of the process chamber including a sensor, where the sensor is configured to measure a concentration of a byproduct of a process (e.g. SiF₄) in the process chamber. The system also includes an exhaust line connected to the outlet gas line of the process chamber and a recirculation line connected to the outlet gas line of the process chamber.

The recirculation line is used for recirculating process gases back to a plasma source. However, some residual gases in an exhaust may have deleterious effects when recirculated back to a plasma source. Accordingly, in some embodiments a filter is disposed in a recirculation line to filter out some residual gases and/or particles in an exhaust before the exhaust is recirculated back to a plasma source. In embodiments, the filter filters out particles and/or byproducts, and does not filter out target gases that can be beneficial to reuse, such as F₂ and/or Ar. In some embodiments, the filter may be a particle filter. Accordingly, embodiments reduce gas waste for beneficial gases without exposing a plasma source to potentially harmful residual gases and/or byproducts in an exhaust.

In some embodiments, a sensor in the process chamber measures an amount of silicon (e.g., SiF₄) in the exhaust of the process chamber during a clean process for the process chamber. The silicon may be a byproduct from one or more processes that deposits on walls of the process chamber. A clean operation of the process chamber may be complete when there is no detectable silicon left in the exhaust and/or when an amount of detected silicon in the process chamber falls below a threshold. The clean process may be stopped when the detected amount of silicon drops below a threshold and/or one or more settings for the clean operation may be adjusted when the amount of silicon in the exhaust reaches a threshold (e.g., falls below the threshold). For example, an amount of NF₃ provided to a plasma source may be reduced when the amount of silicon falls below a threshold to slow down the clean process. This may be performed to reduce the risk of exposing a cleaned chamber surface to corrosive fluorine radicals. Accordingly, a chamber life of a process chamber may be increased according to embodiments.

Embodiments discussed herein provide a system that can measure the amount of byproducts (e.g. silicon tetrafluoride) in the exhaust of the process chamber, filter the exhaust to remove unwanted particles or byproduct gases, and control the incorporation of recovered gases in a continuous production process.

In some embodiments the process chamber (or an inlet gas line connecting the remote plasma source to the process chamber) includes one or more specialized sensors that are configured to detect particular species. The sensors may be sensor devices that employ specialized coatings on surfaces of piezoelectric materials that oscillate at measurable resonant frequencies. The coating acts as a filter that filters out all molecules except for those of a target gas species. An example of such a piezoelectric material that may be used is quartz. For example, embodiments include a quartz crystal microbalance (QCM) with such a specialized coating on one surface of the QCM. The specialized coatings are designed for specific applications and are reactive to select molecular gas species used in those specific applications (without being reactive to other gas species). Examples of applications that the sensor devices may be designed for include etch operations, plasma assisted deposition processes (e.g., plasma assisted atomic layer deposition), plasma clean operations, and so on. The coating on the piezoelectric material changes mass based on a reaction of the coating to the select molecular gas species (e.g., a particular molecule). The change in the coating's mass causes the resonant frequency at which the piezoelectric material oscillates to change. This change in the resonant frequency is measurable and may be used to determine the quantity of the molecular species that reacted with the coating. Accordingly, the sensor devices can directly measure specific molecular species of gases (e.g., fluorine radicals, etc.). Such direct measurement enables closed loop control of plasma sources.

Incorporating a filtration system into the exhaust line of a processing chamber and directing filtered recycled materials (e.g., SiF₄, F₂ and/or Ar) to a plasma source mitigates waste of valuable materials. Sensor devices as described in embodiments account for the measurement and accurate use of recovered gases.

Without the ability to have a quantitative measurement of the concentration of a species, such as SiF₄, closed loop control of the processing environment is not possible. Closed loop control refers to the use of quantitative measurements as a feedback signal to a controller in order to modify processing conditions in an ongoing process. For example, in the case of the measurement of SiF₄, the concentration can be measured, and the measured value can be compared to a setpoint value. When the measured value is below the setpoint value, a first valve connected to a recirculation line is opened to release the exhaust of the processing chamber through the recirculation line, and a second valve connected to the exhaust line is closed. In some embodiments, the first valve and second valve are portions of a two-way valve. As such, more stable and reproducible processes (e.g., clean processes) can be implemented in embodiments. It is understood that the process described herein is applicable for any byproduct and is not limited to silicon fluoride, or silicon tetrafluoride. For simplicity of explanation of the present disclosure, the byproduct will be described as silicon fluoride, or silicon tetrafluoride, which is a fluorine-containing byproduct of a reaction of fluorine with a silicon-containing film on an interior surface of a process chamber that may be formed during processes such as deposition processes, etch processes, and so on.

Embodiments disclosed herein include a sensor such as a non-dispersive infrared sensor that can detect an amount of SiF₄ in an exhaust of a process chamber. Additionally, in some embodiments, a processor that includes of a piezoelectric oscillator (e.g., a QCM) having a surface that is coated with a film that is reactive to a target species of a target gas or molecule (e.g., fluorine radicals), but that is not reactive to other molecules of the gas or molecule or to radical or stable species of other gases or molecules that are flowed together with the target gas or molecule. The one or more sensors may be used for closed loop control of plasma sources. The combination of these components may enable a controller to finely control a plasma process (e.g., a plasma clean process), determine when to stop the plasma process, and reuse process gases. Combined, these features may maximize the life span of process chambers and their components, reduce an amount of process gases that are used, and maximize tool up-time for process chambers.

The system of the present disclosure further includes a gas panel that is configured to deliver at least one gas to the remote plasma source, wherein the at least one gas may include NF₃, F₂, C₂F₆, SF₆, SiCl₄, HBr, NF₃, CF₄, CHF₃, CH₂F₃, Cl₂ and SiF₄, Ar, N₂, He, or a combination thereof. In some embodiments, the remote plasma source may include a gas distribution assembly connected to a gas outlet for delivering excited gases to the processing chamber. In some embodiments, the excited gases may include fluorine radicals. The fluorine radicals may include NF₃, F₂, NF, NF₂, or a combination thereof.

In some embodiments, the fluorine radicals may interact with a silicon-containing layer on surfaces of the processing chamber to generate a byproduct, such as silicon tetrafluoride.

In some embodiments, a filter may be coupled to a recirculation line. The filter may be a particle filter, that is configured to remove particles of unwanted byproducts and/or unwanted gases. In some embodiments, the filter is configured to receive the exhaust from the processing chamber and may filter out one or more first compounds from the exhaust and provide filtered exhaust including one or more second compounds to the input of the radical plasma source.

In some embodiments, the system may further include a pump to provide the filtered exhaust to the input of the remote plasma source.

In some embodiments, the controller of the system may be further configured to determine that the measured concentration of a byproduct, such as SiF₄, in the process chamber exceeds a threshold, which may cause a first valve connecting the process chamber to the recirculation line to close and cause a second valve connecting the process chamber to the exhaust line to open to release the exhaust of the process chamber through the exhaust line.

In some embodiments, the controller of the system may be further configured to determine that the measured concentration of the byproduct (SiF₄) in the process chamber is below a threshold, which may cause a first valve connecting the process chamber to the recirculation line to open to release the exhaust of the process chamber through the recirculation line, and cause a second valve connecting the process chamber to the exhaust line to close.

In another embodiment of the present disclosure, a method of performing the plasma based system is provided. The method includes generating a plasma using a remote plasma source, wherein the plasma may include fluorine radicals as described herein. The method further includes monitoring a concentration of a byproduct of a process (e.g. SiF₄) in an exhaust of a process chamber using a sensor, where the sensor can be any of the sensors as described herein. The method also includes releasing an exhaust from the process chamber through an exhaust line or a recirculation line based on the measured concentration of the byproduct in the exhaust of the process chamber.

In some embodiments of the method, the method may further include determining that the concentration of the byproduct (SiF₄) is higher than a concentration threshold, and responsive to determining that the concentration of the byproduct (SiF₄) is higher than the concentration threshold, causing a first valve connecting the process chamber to the recirculation line to close and causing a second valve connecting the process chamber to the exhaust line to open to release the exhaust of the process chamber through the exhaust line.

In other embodiments of the method, the method may further include determining that the concentration of the byproduct (SiF₄) is lower than a concentration threshold, and responsive to determining that the concentration of the byproduct (SiF₄) is lower than the concentration threshold, causing a first valve connecting the processing chamber to the recirculation line to open to release the exhaust of the processing chamber through the recirculation line and causing a second valve connecting the processing chamber to the exhaust line to close.

In some embodiments, the method may further include recirculating at least a portion of exhaust from the processing chamber to the remote plasma source.

In some embodiments, the method may further include filtering one or more residual gases in the exhaust from the processing chamber prior to recirculating at least the portion of the exhaust to the remote plasma source, wherein fluorine radicals may be recirculated to the remote plasma source. In some embodiments, the fluorine radicals may include NF₃, F₂, NF, NF₂, or a combination thereof.

For simplicity of explanation of the present disclosure, the byproduct will be described as silicon fluoride, or silicon tetrafluoride, which is a fluorine-containing byproduct of a reaction of fluorine with a silicon-containing film on an interior surface of a process chamber that may be formed during processes such as deposition processes, etch processes, and so on. However, it should be understood that the plasma-based cleaning processes discussed herein can also be performed based on measurement of other byproducts, such as other fluorine-containing byproducts. The specific species of byproduct would depend, for example, on the composition of a film to be removed from a chamber interior during cleaning and on a gas (e.g., a plasma) used for the cleaning, and on a reaction of the cleaning gases with such a film. In some embodiments, in which a cleaning gas other than fluorine is used, the byproduct may not be a fluorine-containing byproduct, but may instead be some other byproduct.

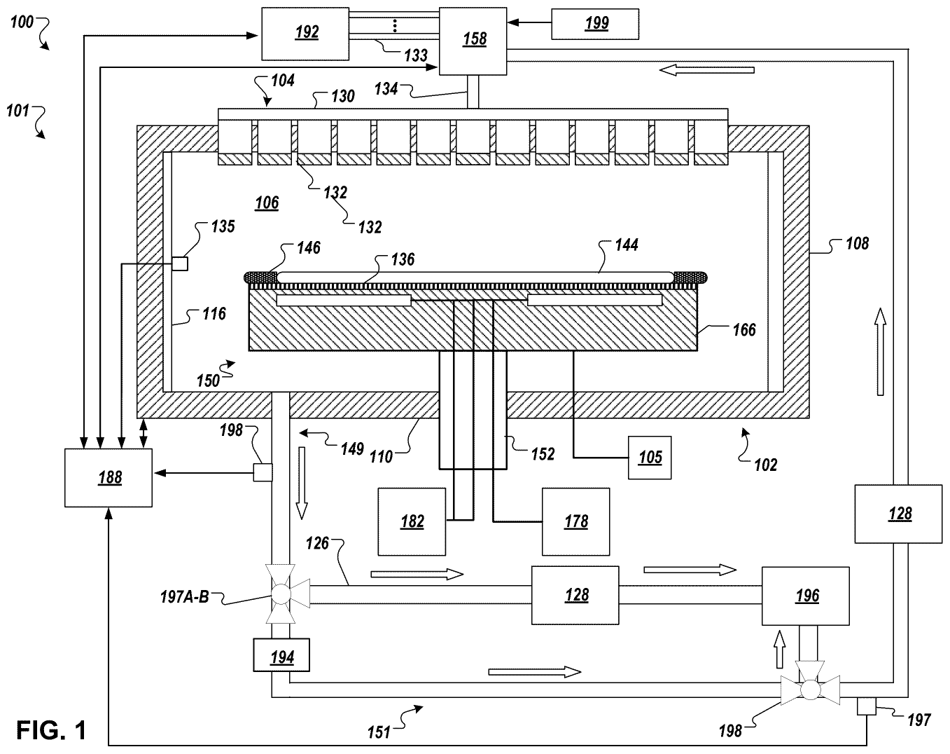

Referring now to the figures, FIG. 1 is a sectional view of a manufacturing system 100 that performs plasma-based processes in embodiments. The manufacturing system 100 may include a gas panel 192 connected to a plasma source 158, such as a remote plasma source, via one or more gas delivery lines 133. The gas delivery lines 133 may deliver gases such as process gases (e.g., chemical vapor deposition (CVD) precursors (e.g., any precursors known in the art, such as SiH₄), ALD precursors, etch gases, cleaning gases (e.g., fluorine containing gases such as NF₃), carrier gases such as Ar, and so on). In embodiments, a different gas delivery line 133 may be used for each of the gases that may be delivered to the plasma source 158.

In one embodiment, gas panel 192 controls the initial concentration of NF₃ and/or Ar gas that flows into the plasma source 158. In some embodiments, the gas panel 192 may be configured to deliver at least one gas to the plasma source 158. In some embodiments, the at least one gas includes NF₃, F₂, C₂F₆, SF₆, SiCl₄, HBr, NF₃, CF₄, CHF₃, CH₂F₃, SiF₄, Cl₂ and SiF₄, Ar, N₂, He, or a combination thereof.

The manufacturing system 100 may further include a process chamber 101 coupled to the plasma source 158 via one or more plasma delivery lines 134. A power source 199 may provide power to the plasma source 158. The plasma source 158 may generate a plasma, from one or more of the gases from gas panel 192, and may deliver the plasma (e.g., a gas containing the plasma) to the process chamber 101 via the one or more plasma delivery lines 134.

The process chamber 101 may be, for example, a plasma etch reactor, a deposition chamber, etc. The process chamber may be suitable for an etching operation, a deposition operation, a chamber cleaning operation, a plasma treatment operation, or any other type of operation typical of a semiconductor manufacturing facility. For example, the process chamber may be configured for performing CVD, ALD, plasma-based etching, and so on.

In an embodiment, one or more substrates (e.g., wafers) 144 may be provided within the process chamber 101. In an embodiment, process chamber 101 may be maintained at a pressure suitable for a target operation. In a particular embodiment, the pressure may be between approximately 1 Torr and approximately 200 Torr. The process chamber 101 may be aged over time by the exposure the processing gases and materials. This aging results in retention of processing species or byproduct species that affect the effective concentration of active processing species in the processing chambers.

The process chamber 101 and/or plasma source 158 may be connected to a controller 188, which may control processing of the plasma source 158, process chamber 101 (e.g., by controlling set points, loading recipes, and so on), and/or the recirculation of recycled exhaust gases. A sensor 135 may be connected to the plasma delivery line(s) 133 and/or may be disposed within the process chamber 101 to detect a concentration of fluorine radicals in a gas or plasma delivered by the remote plasma source 158 to processing chamber 101. In embodiments, the plasma source, such as RPS, 158 includes or is connected to power source 199 that is connected to deliver plasma-generating power to an energy conduit and/or to a gas distribution assembly that is further connected to a gas outlet configured to deliver excited gases to the processing chamber 101. In some embodiments, one or more settings of the RPS 158 include a power provided to the RPS 158 by the power source. Another setting for the RPS 158 may include a plasma frequency. Other settings that may affect a generated plasma (e.g., a concentration of fluorine radicals in a generated plasma) include a pressure in processing chamber 101, flow rates of one or more gases (e.g., process gasses such as NF₃), process time, and so on. In some embodiments, the excited gases provided from remote plasma source 158 to processing chamber 101 include fluorine radicals (e.g., F*). In some embodiments the gases provided from remote plasma source 158 to process chamber 101 further include NF₃, F₂, NF, NF₂, or a combination thereof.

In some embodiments, the excited gases may include nitrogen-based radicals.

In embodiments, the fluorine and/or nitrogen-based radicals may react with silicon based compounds in the process chamber to form SiF₄ as a gaseous byproduct. For example, a cleaning process may be performed to clean a residual film formed on walls of the process chamber during an etch or deposition process. The cleaning process may be performed after a substrate has been removed from the process chamber in embodiments.

In some embodiments, a sensor 135 is provided in the process chamber 101 to measure the concentration of fluorine radicals. In some embodiments, a sensor is provided in process chamber 101 to measure a concentration of SiF₄ gaseous byproduct.

A gas outlet 149 of process chamber 101 may include a sensor 198 for detecting a concentration of silicon (e.g., a concentration of a silicon fluoride such as a concentration of SiF₄) in an exhaust of the process chamber 101. In some embodiments, if the concentration falls above or below a concentration threshold, this may trigger a response in the system 100. The gas outlet 149 may be coupled to an exhaust line 126 via a first valve 197A and may be coupled to a recirculation line 151 via a second valve 197B. In embodiments, the first valve 197A and second valve 197B are portions of a dual-valve assembly 197A-B. A controller 188 may receive the measurement indicating the concentration of SiF₄, and may determine whether to connect the gas outlet 149 to the exhaust line 126 to send the exhaust to abatement 196 or to connect the gas outlet 149 to the recirculation line 151 to recirculate the exhaust. For example, if the concentration of the SiF₄ is above a concentration threshold, first valve 197B connecting the process chamber 101 to the recirculation line 151 is closed, and second valve 197A connecting the process chamber 101 to the exhaust line 126 is opened to release the exhaust of the process chamber through the exhaust line 126. In another example, if the concentration of the SiF₄ is below the concentration, first valve 197B connecting the process chamber 101 to the recirculation line 151 is opened to release the exhaust of the process chamber through the recirculation line 151, and second valve 197A connecting the process chamber 101 to the exhaust line 126 is closed.

As indicated, in some embodiments the one or more settings of the remote plasma source 158 include a power output by the power source 199. In embodiments, controller 188 adjusts one or more settings of at least one of the RPS 158 or the process chamber 101 based on the measured concentration of silicon based compounds, i.e. SiF₄, measured by sensor 198 and/or based on a measured amount of fluorine radicals in chamber in the process chamber 101 measured by sensor 135. In some embodiments, the one or more settings of at least one of the RPS 158 or the process chamber 101 includes at least one of a pressure within the processing chamber, a flow of excited gases to the processing chamber, a power of the RPS, or a frequency of the RPS.

In an embodiment, the manufacturing system 100 may comprise a sensor 135 that is fluidically coupled to the process chamber 101 and/or to the plasma delivery line(s) 134. For example, a valve may be provided along a tube between the processing chamber 101 and the sensor 135. In an embodiment, the valve is a type of valve that allows for an unobstructed line of sight between the processing chamber 101 and the sensor 135. For example, the valve may be an isolation gate valve. An isolation gate valve may allow for a binary state of operation. That is, the valve may be open (i.e., 1) or closed (i.e., 0). When the valve is open, the line of sight is unobstructed. Alternately, another type of valve such as a needle valve may be used.

In embodiments, the sensor 135 comprises a piezoelectric substrate in a holder. The piezoelectric substrate is made to oscillate at a resonant frequency by applying an alternating current to the piezoelectric substrate. One or more surface of the piezoelectric substrate is coated by a film that is reactive to a narrow range of molecular species. In particular, the film is composed of a material that is reactive to a target molecular species of a particular target gas from among gases being used in a process. In one embodiment, the radical sensor comprises a QCM having at least one coated surface that is coated with a film that is selectively reactive to radicals of a particular gas. The radical sensor 135 is described in greater detail below with reference to the proceeding figures.

In some embodiments, the sensor 135 is a QCM sensor. The QCM sensor base may include a thin plate of quartz crystal that oscillates in the thickness-shear mode because such a QCM sensor base has high sensitivity to mass change on the crystal. The piezoelectric nature of quartz crystal allows the crystal to be driven into oscillation and with its resonant frequency measured by simple electrical means. In embodiments, the quartz crystal is precisely cut at certain angles with respect to its crystallographic axes. In embodiments, the quartz crystal is an AT-cut quartz crystal.

In some embodiments, sensor 135 is a QCM sensor having a coating that is reactant to fluorine radicals. In one embodiment, QCM sensor includes a silicon dioxide coating, or other coating that acts as a filter to react with fluorine radicals.

In one embodiment, in order to measure an amount of positively and/or negatively charged radicals, a pair of radical sensors may be used. A first radical sensor may include the charged gratings, and a second radical sensor may not include the charged gratings. All radicals of a target gas species may be detected by the second radical sensor, and only neutral radicals of the target gas species may be detected by the first radical sensor. A difference between the measurements of the two radical sensors may then be computed to determine an amount of the radicals detected by the second radical sensor that were attributable to charged radicals. The grating may be modified to only filter out positively charged molecules/ions or to only filter out negatively charged molecules. Accordingly, by combining two or more radical sensors, each with a different grating configuration (e.g., one not including any grating), an amount of positively charged radicals may be detected, an amount of negatively charged radicals may be detected, and/or an amount of neutral radicals may be detected.

In embodiments, the plasma source 158 is a remote plasma source (RPS) that generates plasma at a remote location and delivers the externally generated plasma to the process chamber 101. Alternatively, the process chamber 101 may include an integrated plasma source (not shown) that can generate plasma within the processing chamber. In either instance, the radical sensor 135 may be disposed within or connected to the process chamber 101 rather than in or connected to the gas deliver lines 133 in embodiments.

Process chamber 101 includes a substrate support assembly 150, according to some embodiments. Substrate support assembly 150 includes a puck 166 (e.g., may include an electrostatic chuck (ESC)). The puck 166 may perform chucking operations, e.g., vacuum chucking, electrostatic chucking, etc. Substrate support assembly 150 may further include a base plate, a cooling plate and/or an insulator plate (not shown).

Process chamber 101 includes chamber body 102 and lid 104 that enclose an interior volume 106. Chamber body 102 may be fabricated from aluminum, stainless steel, or other suitable material. Chamber body 102 generally includes sidewalls 108 and a bottom 110. An outer liner 116 may be disposed adjacent to side walls 108, e.g., to protect chamber body 102. Outer liner 116 may be fabricated and/or coated with a plasma or halogen-containing gas resistant material. Outer liner 116 may be fabricated from or coated with aluminum oxide. Outer liner 116 may be fabricated from or coated with yttria, yttrium alloy, oxides thereof, etc.

Lid 104 may be supported on sidewall 108 of chamber body 102. Lid 104 may be openable, allowing access to interior volume 106. Lid 104 may provide a seal for process chamber 101 when closed. Plasma source 158 may be coupled to process chamber 101 to provide process, cleaning, backing, flushing, etc., gases and/or plasmas to interior volume 106 through gas distribution assembly 130. Gas distribution assembly 130 may be integrated with lid 104.

Examples of processing gases that may be used in process chamber 101 include halogen-containing gases, such as C₂F₆, SF₆, SiCl₄, HBr, NF₃, CF₄, CHF₃, CH₂F₃, Cl₂ and SiF₄. Other reactive gases may include O₂ or N₂O. Non-reactive gases may be used for flushing or as carrier gases, such as N₂, He, Ar, etc. Gas distribution assembly 130 (e.g., showerhead) may include multiple apertures 132 on the downstream surface of gas distribution assembly 130. Apertures 132 may direct gas flow to the surface of substrate 144. In some embodiments, gas distribution assembly may include a nozzle (not pictured) extended through a hold in lid 104. A seal may be made between the nozzle and lid 104. Gas distribution assembly 130 may be fabricated and/or coated by a ceramic material, such as silicon carbide, yttrium oxide, etc., to provide resistance to processing conditions of process chamber 101.

Substrate support assembly 150 is disposed in interior volume 106 of process chamber 101 below gas distribution assembly 130. Substrate support assembly 150 holds a substrate 144 during processing. An inner liner (not shown) may be coated on the periphery of substrate support assembly 148. The inner liner 118 may share features (e.g., materials of manufacture, function, etc.) with outer liner 116.

Substrate support assembly 150 may include supporting pedestal 152, insulator plate, base plate, cooling plate, and puck 166. Puck 166 may include electrodes 136 for providing one or more functions. Electrodes may include chucking electrodes (e.g., for securing substrate 144 to an upper surface of puck 166), heating electrodes, RF electrodes for plasma control, etc.

Protective ring 146 (e.g. a process kit ring, an insert ring, and/or a support ring) may be disposed over a portion of puck 166 at an outer perimeter of puck 166. Puck 166 may be coated with a protective layer (not shown). Protective layer 136 may be a ceramic such as Y₂O₃ (yttria or yttrium oxide), Y₄Al₂O₉ (YAM), Al₂O₃ (alumina), Y₃Al₅O₁₂ (YAG), YAlO₃ (YAP), quartz, SiC (silicon carbide), Si₃N₄ (silicon nitride), Sialon, AlN (aluminum nitride), AlON (aluminum oxynitride), TiO₂ (titania), ZrO₂ (zirconia), TiC (titanium carbide), ZrC (zirconium carbide), TiN (titanium nitride), TiCN (titanium carbon nitride), Y₂O₃ stabilized ZrO₂ (YSZ), and so on. The protective layer may be a ceramic composite such as YAG distributed in an alumina matrix, a yttria-zirconia solid solution, a silicon carbide-silicon nitride solid solution, or the like. The protective layer may be sapphire or MgAlON.

Puck 166 may further include multiple gas passages such as grooves, mesas, and other features that may be formed in an upper surface of puck 166. Gas passages may be fluidly coupled to a gas source 105. The gas outlet 105 further delivers SiO₂, H₂, or a combination thereof. Gas from gas source 105 may be utilized as a heat transfer or backside gas, may be utilized for control of one or more lift pins of puck 166, etc. Multiple gas sources may be utilized (not shown). Gas passages may provide a gas flow path for a backside gas such as He via holes drilled in puck 166. Backside gas may be provided at a controlled pressure into gas passages to enhance heat transfer between puck 166 and substrate 144.

Puck 166 may include one or more clamping electrodes. The clamping electrodes may be controlled by chucking power source 182. Clamping electrodes may further couple to one or more RF power sources through a matching circuit for maintaining a plasma formed from process and/or other gases within process chamber 101. The RF power sources may be capable of producing an RF signal having a frequency from about 50 kilohertz (kHz) to about 3 gigahertz (GHz) and a power of up to about 10,000 Watts. Heating electrodes of puck 166 may be coupled to heater power source 178.

As mentioned, a gas outlet 149 is connected to process chamber body 102. The gas outlet 149 may couple to exhaust line 126 via valve 197A and/or to recirculation line 151. Exhaust line 126 may include a pump system 128. Pump system 128 may include one or more pumps, valves, lines, manifolds, tanks, etc., utilized to evacuate and regulate the pressure of interior volume 106. Exhaust line 126 may include valve 197A that may direct gases to pump system 128 and on to abatement 196.

In embodiments, sensor 198 may be coupled to the gas outlet 149. The sensor 198 may be connected to the gas outlet 149 upstream of one or more valves connecting the gas outlet 149 to exhaust line 126 and/or recirculation line 151. Sensor 198 may measure the concentration of one or more gases in an exhaust from process chamber 101. In one embodiment, sensor 198 is configured to measure a concentration of one or more silicon-containing species in the exhaust. In one embodiment, sensor 198 is configured to measure an amount of SiF₄ in the exhaust. In one embodiment, second sensor is configured to measure at least one of NF₃ or fluorine radicals in the exhaust. In some embodiments, sensor 198 is a non-dispersive infrared sensor. In some embodiments, sensor 198 is an electrochemical sensor, a photionization detector (PID), a gas chromatography sensor, a metal oxide semiconductor sensor, an ion mobility spectrometry sensor, or a surface acoustic wave sensor configured to measure silicon species such as SiF₄. In some embodiments, sensor 198 is connected to controller 188 to provide sensor measurements to controller 188. Based on sensor measurements from sensor 198, controller 188 may determine an amount of silicon that is being removed from an interior of process chamber 101. A silicon-containing film may build up on exposed surfaces of the interior volume 106 of process chamber during deposition processes in embodiments. Cleaning processes may periodically be performed to remove the buildup of silicon-containing film. As the film is reduced, the amount of silicon-containing species in the exhaust may also be reduced. This information may be used by controller 188 to determine how close a clean process is to complete and/or whether a clean process is complete. For example, if no silicon-containing species are detected, then controller 188 may determine that a clean process is complete. If a reduced amount of silicon-containing species is detected (e.g., an amount less than a threshold), then controller 188 may determine that a clean process is close to complete. This may prompt controller 188 to adjust a clean process (e.g., by reducing an amount of fluorine-containing gas (e.g., NF₃) to plasma source, by reducing a plasma power, by reducing a plasma frequency, etc.). This may reduce a chance that the process chamber 101 is exposed to more fluorine-based plasma after cleaning is complete. Additionally, the concentration of SiF₄ may be used to determine whether to recirculate an exhaust of the process chamber 101 to reuse fluorine from the exhaust or to send the exhaust to abatement 196.

In embodiments, manufacturing system 100 includes recirculation system 151, which recirculates at least a portion of the exhaust from processing chamber 101 back to plasma source 158. Fluorine-containing gases may be expensive, and may also be substantial greenhouse gases. Accordingly, it is beneficial in embodiments to reduce an amount of fluorine-based gases that are used in processes such as plasma-based processes. Often not all of the fluorine (or other active species) in a plasma get used. As a result, the exhaust from process chamber 101 may contain useful gases that could be reused. Reuse of such useful gases (e.g., F₂, Ar, etc.) may reduce an amount of gases that are supplied to plasma source 158 from gas panel 192. Accordingly, recirculation system 151 recirculates some gases in exhaust back to plasma source 158 in embodiments.

In some embodiments a filter 194 is disposed in recirculation line 151. Filter 194 may filter out particles in the exhaust that might be harmful to plasma source 158 and/or that may not be useful, and may allow gases such as Ar, SiF₄, and F₂ to pass through.

In some embodiments, the recirculation system 151 may be shut down if there is an issue within such system. For example, a sensor within the recirculation system 151, such as the mass flow sensor 197, is malfunctioning, then the recirculation system can be stopped. Other issues that may occur include, but are not limited to, clogs in the filter 194 or line to the filter, pressure fluctuation within the recirculation system and/or other malfunctions with sensors or pumps. If the issue occurs, then the manufacturing system may be adjusted to shut down the recirculation system.

Pump system 128 may output exhaust gases to abatement system 196. Abatement system 196 may dispose of the output gases, such as by burning the output gases in the exhaust.

In embodiments, a pump 128 is connected to recirculation line 151 to pump the exhaust from the process chamber 101 back to the remote plasma source 158.

In some embodiments, a mass flow monitor 197 may be connected to recirculation system 151 to detect a an amount of one or more gases in the recirculation line. The mass flow sensor 197 may be configured to detect all gases, or a subset of gases, such as at least one of F₂, SiF₄, HF, Ar, N₂, or O₂.

Controller 188 may control an amount of fluorine that is provided to plasma source 158 in embodiments. Controller 188 may receive measurements from third sensor 197 to determine an amount of fluorine that is delivered to plasma source 158 from recirculation system 151. Controller 188 may determine a target amount of fluorine to be delivered to plasma source 158, and may subtract the amount of fluorine provided by recirculation system 151 from the target amount of fluorine. A remaining difference in amount of fluorine may be provided by a fluorine-rich gas (e.g., NF₃) from gas panel 192. Accordingly, controller 192 may reduce an amount of NF₃ or other fluorine-containing gas delivered to plasma source 158 from gas panel 192 based on the data from third sensor 197 in embodiments.

In some embodiments, the controller 188 may further adjust the one or more settings of at least one of the RPS 158 or the process chamber 101 based on the measured amount of gas as measured by mass flow monitor 197, such as described above.

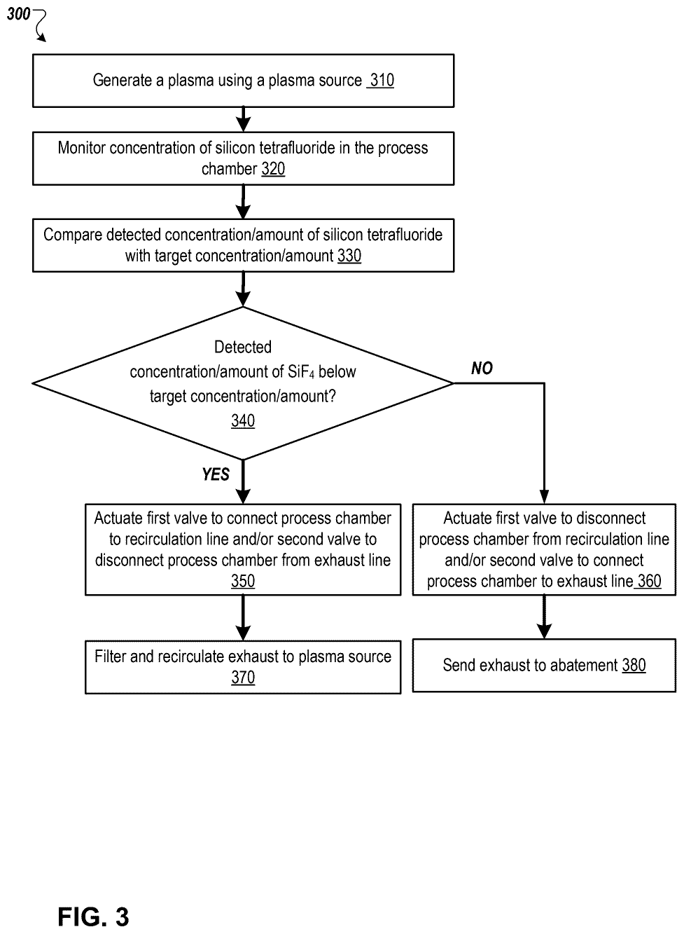

As touched on above, controller 188 (also referred to as a system controller) may control one or more parameters and/or set points of the plasma source 158 and/or process chamber 101. Controller 188 can be and/or include a computing device such as a personal computer, a server computer, a programmable logic controller (PLC), a microcontroller, and so on. Controller 188 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. Controller 188 can include a data storage device (e.g., one or more disk drives and/or solid state drives), a main memory, a static memory, a network interface, and/or other components. Controller 188 can execute instructions to perform any one or more of the methodologies and/or embodiments described herein. The instructions can be stored on a computer readable storage medium, which can include the main memory, static memory, secondary storage and/or processing device (during execution of the instructions). In embodiments, execution of the instructions by controller 188 causes controller 188 to perform the methods of FIGS. 3 and/or 4. For example, controller 188 may receive measurements from second sensor 198 indicating a concentration of one or more byproduct species (e.g., SiF₄) that result from the radicals interacting with surfaces in processing chamber 101, and/or may receive measurements from mass flow monitor 197 indicating an amount of one or more target gases to be recirculated back to plasma source 158. Controller 188 may adjust one or more properties or settings (e.g., such as a plasma power, flow rate of one or more gases to plasma source, etc.) of plasma source 158 responsive to the measured radical concentration measured by sensor 135, the measured byproduct concentration measured by sensor 198 and/or the measured amount of gas recirculated to plasma source 158 as measured by mass flow monitor 197. Controller 188 may additionally adjust one or more properties of process chamber 101, such as pressure. Controller 188 can also be configured to permit entry and display of data, operating commands, and the like by a human operator.

In some embodiments, recirculation line 151 includes a valve 198 that may be opened to divert some exhaust to abatement 196 (e.g., to maintain a target pressure).

In embodiments, the sensor 135 may be a radical sensor. In some embodiments, radical sensor comprises a QCM sensor base. A piece of solid material of any shape can normally oscillate at certain resonant frequencies. By increasing the mass of the vibrating unit, the typical result is the decrease of that solid material's resonant frequencies. This is the basic principle of a QCM.

The QCM sensor base may include a thin plate of quartz crystal that oscillates in the thickness-shear mode because such a QCM sensor base has high sensitivity to mass change on the crystal. The piezoelectric nature of quartz crystal allows the crystal to be driven into oscillation and with its resonant frequency measured by simple electrical means. In embodiments, the quartz crystal is precisely cut at certain angles with respect to its crystallographic axes. In embodiments, the quartz crystal is an AT-cut quartz crystal.

The QCM sensor base including the crystal and electrodes measures the Areal Mass Density (mass per unit area) of a material which uniformly covers the sensitive area on the sensing crystal. For heavy loading on the crystal, its accuracy depends on the knowledge of the shear-mode acoustic impedance value of the deposited material. Larger crystals do not have higher sensitivity. The QCM is not a weighing device because it does not require a gravitational force. It can be used in space with zero gravity. In embodiments, a thickness reading t_{f} may be derived from the areal mass density value, which is equivalent to t_{f}ρ_{f}, by using the density of the film ρ_{f}. The entry of a wrong density value results a wrong thickness reading. The areal mass density measurement is in absolute value in embodiments. In embodiments, no calibration is needed for a properly designed QCM. Temperature variation, stress, gas adsorption and desorption, surface reaction, etc. can all give false signals.

The QCM can measure mass on a sensing surface of the QCM according to the equation

$$\frac{m}{A} ∝ ρ {t}^{n} ,$$

where m/A is mass per unit area, ρ is density of a material on a sensing surface of the QCM, t is thickness and n a constant (≥0) where for linear dependence n is equal to 1. In embodiments, the sensitivity of QCM can be down to better than 1×10⁻⁹ g/cm². In terms of thickness for a material, say, Al, with density ρ=2.7 g/cm³, this QCM sensitivity is equivalent to 0.1 Å of Al. Thickness change expressed in terms of mass per unit area, or areal mass density, is more appropriate at subatomic sizes.

A piezoelectric resonator can be represented by a simple equivalent circuit for electrical analysis. The mechanical behavior of a quartz crystal resonator (e.g., QCM) can be represented by an electrical equivalent model as shown. This is the so-called the Butterworth van Dyke (BVD) electrical model of a quartz crystal resonator. In the motional arm (the upper branch) of the BVD model, it consists of three components that determine the series resonance frequency of the quartz crystal plate. Rₐ corresponds to the energy dissipation due to mechanical coupling between the crystal and its holder. For QCM applications, added mass load on the crystal surface also causes Rₐ to increase. Lₐ corresponds to the mass being displaced during oscillation. For QCM applications, the total mass includes that of the crystal, the electrodes, and the deposited thin film materials. Cₐ corresponds to the stored energy in the oscillator that is related to the elastic properties of quartz, electrodes, and the deposited materials. The parasitic capacitance Co represents the total static capacitances of the crystal electrodes, the holder, and the connecting cable.

In one embodiment, in order to measure an amount of positively and/or negatively charged radicals, a pair of radical sensors may be used. A first radical sensor may include the charged gratings or grids, and a second radical sensor may not include the charged gratings or grids. All radicals of a target gas species may be detected by the second radical sensor, and only neutral radicals of the target gas species may be detected by the first radical sensor. A difference between the measurements of the two radical sensors may then be computed to determine an amount of the radicals detected by the second radical sensor that were attributable to charged radicals. The grating may be modified to only filter out positively charged molecules/ions or to only filter out negatively charged molecules. Accordingly, by combining two or more radical sensors, each with a different grating configuration (e.g., one not including any grating), an amount of positively charged radicals may be detected, an amount of negatively charged radicals may be detected, and/or an amount of neutral radicals may be detected.

FIG. 3 is a flow chart of one embodiment for a method 300 of controlling a plasma process using measurement of silicon tetrafluoride (SiF₄) concentration. At block 310 of method 300, a plasma source generates a plasma. The plasma may be generated by a remote plasma source (e.g., a plasma source external to a process chamber) or by a local plasma source (e.g., a plasma source internal to a process chamber). At block 320, a sensor (e.g., as described hereinabove) is used to detect a concentration/amount of SiF₄ in an exhaust from a process chamber. The concentration of SiF₄ in the exhaust may be directly related to the rate of the process of the process chamber (e.g. cleaning, etching, deposition, etc.), to an amount of a silicon-based byproduct on chamber components, and/or on other factors. The concentration of the SiF₄ has been found to have a relationship to the amount of fluorine radicals within the process chamber. That is, as the concentration of SiF₄ decreases, then the amount of fluorine radicals increases. Alternatively, when the amount of SiF₄ increases, then the amount of fluorine radicals decreases.

At block 330, processing logic compares the detected concentration/amount of SiF₄ to a target concentration/amount of SiF₄. At block 340, processing logic determines whether the detected concentration/amount of SiF₄ is above or below a concentration threshold. If the amount of SiF₄ is below the concentration threshold, the method continues to block 350. If the amount of SiF₄ is at or above the concentration threshold, the method continues to block 360. In some embodiments, processing logic determines whether the detected SiF₄ concentration differs from the target concentration/amount by more than a difference threshold (e.g., if a difference between the target concentration and the detected concentration is more than a difference threshold). If the difference exceeds a difference threshold, then the method may proceed to block 350 or block 360 as previously indicated. If, however, the difference amount is less than the difference threshold, then processing logic may continue to flow the exhaust to whatever line it was previously flowing the exhaust to. For example, if the difference is less than the difference threshold and the process chamber was previously connected to the recirculation line, then the controller may not actuate any valves and may continue to flow the exhaust to the recirculation line. Similarly, if the difference is less than the difference threshold and the process chamber was previously connected to the exhaust line, then the controller may not actuate any valves and may continue to flow the exhaust to the exhaust line.

At block 350, processing logic actuates a first valve to connect the process chamber to the recirculation line and/or a second valve to disconnect the process chamber from the exhaust line. After releasing the exhaust to the recirculation line, then the method proceeds to block 370, where the exhaust is filtered into the recirculation system as described herein.

In some embodiments, a pressure sensor is included in the recirculation line and/or in the process chamber, and the measured pressure is compared to a pressure threshold. If the measured pressure exceeds a pressure threshold, then processing logic may actuate a valve that connects the recirculation line to abatement to redirect some of the exhaust from the recirculation line to abatement.

At block 360, processing logic actuates a first valve to disconnect the process chamber from the recirculation line and/or a second valve to connect the process chamber to the exhaust line. After releasing the exhaust to the exhaust line, then the method proceeds to block 380, where the exhaust is sent to abatement as described herein.

In some embodiments, a cyclic pattern of recycled gas and fresh NF₃ gas can be used to control SiF₄ concentration during a plasma process (e.g., during a plasma cleaning process). In an example, for a first period of time (e.g., a first 10-50 seconds) an exhaust from the process chamber is recirculated back to the plasma source. During this time, the amount of SiF4 in the exhaust will steadily rise, and the SiF₄ is being recirculated back into the process chamber, while additional SiF₄ is also being created. Once the amount of SiF₄ in the exhaust reaches a threshold amount, the exhaust may be redirected to the exhaust line and sent to abatement. The process chamber may be connected to abatement for a second amount of time (e.g., 5-30 seconds) until the amount of SiF₄ falls below the threshold or a second threshold that is lower than the threshold (e.g., reaches approximately 0 parts per million). The process may then repeat, and the process chamber may then be disconnected from the exhaust line (and abatement), and reconnected to the recirculation line for the first amount of time. The pulse frequency and time can vary in the cycle based on the process. In some embodiments, a purge of inert gas such as N₂ and/or Ar may be flowed into the process chamber and/or recirculation line between clean cycles (e.g., to purge the recirculation line after it is no longer recirculating the exhaust back to the plasma source).

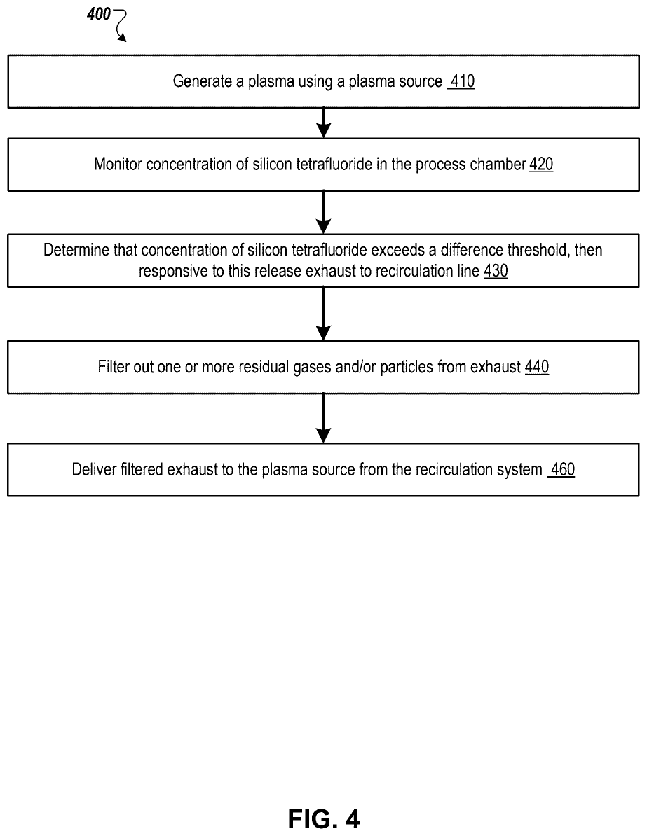

FIG. 4 is a flow chart of one embodiment for a method 400 of controlling SiF₄ concentration in a plasma via a remote plasma source (or integrated plasma source), a sensor, and recycled filtered process exhaust. At block 410 of method 400, a plasma source generates a plasma. The plasma may be generated by a remote plasma source (e.g., a plasma source external to a process chamber) or by a local plasma source (e.g., a plasma source internal to a process chamber). At block 420, a sensor (e.g., as described hereinabove) is used to detect a concentration/amount of SiF₄ in the plasma.

At block 430, the measured concentration of SiF₄ is compared to a concentration threshold. If the measured concentration is below the concentration threshold, then a valve is opened as described herein to release the exhaust from the process chamber to the recirculation line.

At block 440, the residual gases and/or unwanted particles in the exhaust from the process chamber are passed through a filter, such as a particle filter, to filter out one or more of the residual gases and unwanted particles. Thus, a filtered exhaust including one or more fluorine radicals is produced.

At block 460, the filtered exhaust including fluorine radicals is delivered to the plasma source that is connected to the recirculation system.

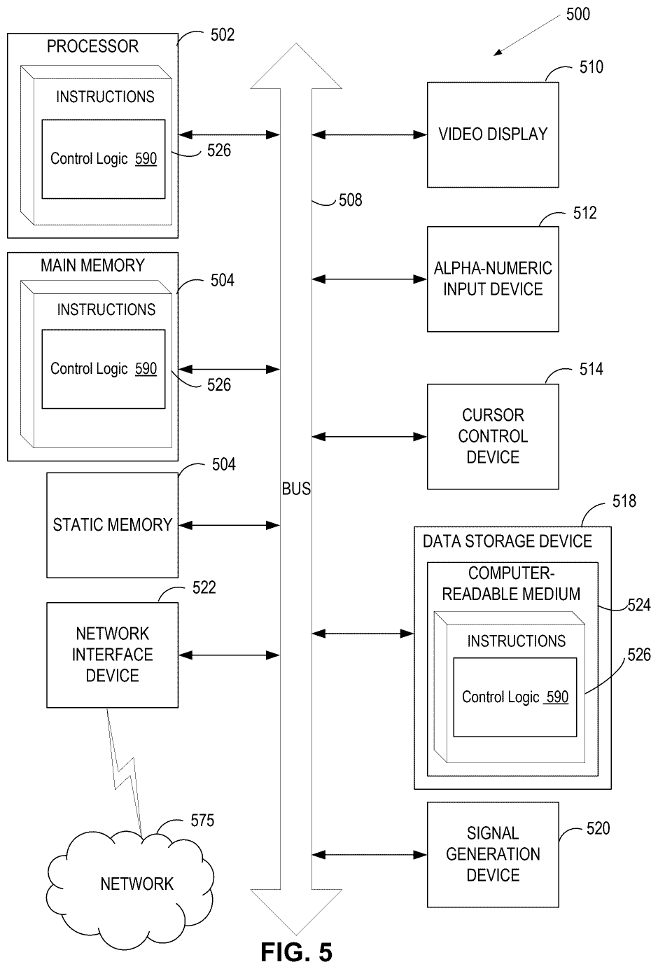

FIG. 5 is a block diagram illustrating a computer system 500, according to some embodiments. In some embodiments, computer system 500 corresponds to controller 188 of FIG. 1. In some embodiments, computer system 500 may be connected (e.g., via a network, such as a Local Area Network (LAN), an intranet, an extranet, or the Internet) to other computer systems. The term “computer” shall include any collection of computers that individually or jointly execute a set (or multiple sets) of instructions to perform any one or more of the methods described herein.

In a further aspect, the computer system 500 may include a processing device 502, a volatile memory 504 (e.g., Random Access Memory (RAM)), a non-volatile memory 506 (e.g., Read-Only Memory (ROM) or Electrically-Erasable Programmable ROM (EEPROM)), and a data storage device 518, which may communicate with each other via a bus 508.

Processing device 502 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 500 may further include a network interface device 522 (e.g., coupled to network 574). Computer system 500 also may include a video display unit 510 (e.g., an LCD), an alphanumeric input device 512 (e.g., a keyboard), a cursor control device 514 (e.g., a mouse), and a signal generation device 520.

In some embodiments, data storage device 518 may include a non-transitory computer-readable storage medium 524 (e.g., non-transitory machine-readable medium) on which may store instructions 526 encoding any one or more of the methods or functions described herein, including instructions for control logic 590 that may monitor concentrations of gases, radicals, etc., and determine changes to process chambers and/or remote plasma sources based on detected concentrations.

Instructions 526 may also reside, completely or partially, within volatile memory 504 and/or within processing device 502 during execution thereof by computer system 500, hence, volatile memory 504 and processing device 502 may also constitute machine-readable storage media.

While computer-readable storage medium 524 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” “reducing,” “generating,” “correcting,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The terms “over,” “under,” “between,” “disposed on,” “support,” and “on” as used herein refer to a relative position of one material layer or component with respect to other layers or components. For example, one layer disposed on, over, or under another layer may be directly in contact with the other layer or may have one or more intervening layers. Moreover, one layer disposed between two layers may be directly in contact with the two layers or may have one or more intervening layers. Similarly, unless explicitly stated otherwise, one feature disposed between two features may be in direct contact with the adjacent features or may have one or more intervening layers.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A system comprising:
a remote plasma source;
a process chamber;
an exhaust line connected to the process chamber;
a sensor in at least one of the process chamber or the exhaust line, wherein the sensor is configured to measure a concentration of a byproduct of a process in an exhaust of the process chamber;
a recirculation line connected to the process chamber; and
a controller to release the exhaust of the process chamber through the exhaust line or the recirculation line based on the measured concentration of the byproduct in the exhaust of the process chamber.

2. The system of claim 1, further comprising:
a gas panel configured to deliver at least one gas to the remote plasma source, wherein the at least one gas comprises NF₃, F₂, C₂F₆, SF₆, SiCl₄, HBr, NF₃, CF₄, CHF₃, CH₂F₃, Cl₂ and SiF₄, Ar, N₂, He, or a combination thereof.

3. The system of claim 1, wherein the remote plasma source comprises a gas distribution assembly connected to a gas outlet for delivering excited gases to the process chamber.

4. The system of claim 3, wherein the excited gases comprise the fluorine radicals, and wherein the byproduct comprises a fluorine-containing byproduct.

5. The system of claim 4, wherein the fluorine radicals comprise NF₃, F₂, NF, NF₂, or a combination thereof, wherein the fluorine-containing byproduct comprises SiF₄, and wherein the fluorine radicals are to interact with a silicon-containing layer on surfaces of the process chamber to generate the SiF₄.

6. The system of claim 1, further comprising:
a filter coupled to the recirculation line, wherein the filter is configured to receive the exhaust from the process chamber, filter out one or more first compounds from the exhaust, and provide filtered exhaust comprising one or more second compounds to the recirculation line.

7. The system of claim 6, wherein the one or more first compounds comprise at least particles of the byproduct, and wherein the one or more second compounds comprise at least one of the fluorine radicals or Ar.

8. The system of claim 6, further comprising a pump to provide the filtered exhaust to the input of the radical plasma source.

9. The system of claim 1, wherein the sensor is a nondispersive infrared sensor.

10. The system of claim 1, wherein the controller further adjusts one or more settings of at least one of the remote plasma source or the process chamber based on the measured concentration of SiF₄.

11. The system of claim 1, wherein the controller is further configured to:
determine that the measured concentration of the byproduct in the process chamber exceeds a threshold;
cause a first valve connecting the process chamber to the recirculation line to close; and
cause a second valve connecting the process chamber to the exhaust line to open to release the exhaust of the process chamber through the exhaust line.

12. The system of claim 1, wherein the controller is further configured to:
determine that the measured concentration of the byproduct in the exhaust of the process chamber is below a threshold;
cause a first valve connecting the process chamber to the recirculation line to open to release the exhaust of the process chamber through the recirculation line; and
cause a second valve connecting the process chamber to the exhaust line to close.

13. The system of claim 1, further comprising:
a radical sensor in the process chamber, wherein the radical sensor is configured to measure a concentration of fluorine radicals in the process chamber.

14. The system of claim 1, wherein the controller is to adjust a flow of a fluorine-based gas to the remote plasma source at least in part on the measured concentration of fluorine radicals in the process chamber.

15. A method comprising:
generating a plasma using a remote plasma source, the plasma comprising fluorine radicals, wherein the fluorine radicals react with a silicon-containing film on one or more components of a process chamber to form a byproduct of a process;
monitoring a concentration of the byproduct in an exhaust of the process chamber using a sensor; and
releasing the exhaust of the process chamber through an exhaust line connected to the process chamber or a recirculation line connected to the process chamber based at least on the concentration of the byproduct in the process chamber.

16. The method of claim 15, further comprising:
determining that the concentration of the byproduct is higher than a concentration threshold; and
responsive to determining that the concentration of the byproduct is higher than the concentration threshold, performing the following, comprising:
causing a first valve connecting the process chamber to the recirculation line to close; and
causing a second valve connecting the process chamber to the exhaust line to open to release the exhaust of the process chamber through the exhaust line.

17. The method of claim 15, further comprising:
determining that the concentration of the byproduct is lower than a concentration threshold; and
responsive to determining that the concentration of the byproduct is lower than the concentration threshold, recirculating at least a portion of exhaust from the process chamber to the remote plasma source.

18. The method of claim 17, further comprising:
causing a first valve connecting the process chamber to the recirculation line to open to release the exhaust of the process chamber through the recirculation line; and
causing a second valve connecting the process chamber to the exhaust line to close.

19. The method of claim 15, further comprising:
filtering one or more residual gases in the exhaust of the process chamber prior to recirculating at least the portion of the exhaust to the remote plasma source, wherein fluorine radicals are recirculated to the remote plasma source.

20. The method of claim 19, wherein the fluoride radicals comprise NF₃, F₂, NF, NF₂, or a combination thereof.
